(19) United States
(12) Patent Application Publication
(10) Pub. No.: US 2014/0174520 A1
(43) Pub. Date: Jun. 26, 2014

(54) THIN FILM PHOTOVOLTAIC CELL AND METHOD OF MANUFACTURE OF SAME

(71) Applicants: Satoshi Sawayanagi, Ichihara-city (JP); Takehito Wada, Funabashi-city (JP); Hiroaki Nakahara, Hino-city (JP); Masaaki Takeuchi, Hino-city (JP)

(72) Inventors: Satoshi Sawayanagi, Ichihara-city (JP); Takehito Wada, Funabashi-city (JP); Hiroaki Nakahara, Hino-city (JP); Masaaki Takeuchi, Hino-city (JP)

(21) Appl. No.: 13/814,837

(22) PCT Filed: Feb. 8, 2012
(86) PCT No.: PCT/JP2012/000828

§ 371 Date: Mar. 11, 2013

(30) Foreign Application Priority Data
Sep. 15, 2011 (JP) 2011-201963

(51) Int. Cl. H01L 31/0224; H01L 21/66; H01L 31/18

(52) U.S. Cl. CPC H01L 31/02245; H01L 31/1884; H01L 22/12
USPC 136/256; 438/80; 438/7

(57) ABSTRACT

A thin film photovoltaic cell has an insulating substrate divided into a plurality of unit cells by alternately forming patterning lines in layers stacked on two faces of the insulating substrate; a rear face electrode layer, a photoelectric conversion layer, and a transparent electrode layer stacked in order on one face of the insulating substrate accordingly; and a back face electrode layer deposited on the other face of the insulating substrate. The photovoltaic cell further has a first penetrating hole penetrating the insulating substrate to electrically connect the transparent electrode layer and the back face electrode layer; a second penetrating hole penetrating the insulating substrate to electrically connect the rear face electrode layer and the back face electrode layer; and a transparent electrode layer removal portion in which the transparent electrode layer at least in a region surrounding the second penetrating hole is removed by an ultraviolet pulsed laser.

### TECHNICAL FIELD

This invention relates to a thin film photovoltaic cell, in which a metal electrode layer, a photoelectric conversion layer and a transparent electrode layer are stacked on a film substrate.

### BACKGROUND ART

FIG. 12 is a plan view of a thin film photovoltaic cell of the prior art. FIGS. 13A, 13B show cross-sectional views along line A-A in FIG. 12, wherein FIG. 13B is an enlarged view of a portion C in FIG. 13A. FIGS. 14A-14B show cross-sectional views along line B-B in FIG. 12, wherein FIG. 14B is an enlarged view of a portion D in FIG. 14A.

As shown in FIGS. 13A, 13B and FIGS. 14A, 14B, the thin film photovoltaic cell 21 of the prior art comprises an insulating substrate 22. If the side of the light-receiving face of the thin film photovoltaic cell 21 is F, and the side opposite the light-receiving face is R, then a metal electrode layer 23 is formed on both the light-receiving face side F and the side opposite the light-receiving side R of the insulating substrate 22. Here, the metal electrode layer 23 on the one face on the light-receiving face side F of the insulating substrate 22 functions as a rear face electrode layer 23a, and the metal electrode layer 23 on the other face which is on the side opposite the light-receiving face R of the insulating substrate 22 functions as a first back face electrode layer 23b.

Further, as shown in FIGS. 13A, 13B and FIGS. 14A, 14B, a photoelectric conversion layer 24 and a transparent electrode layer 25 are stacked in this order on the rear face electrode layer 23a. On the first back face electrode layer 23b is stacked a second back face electrode layer 26.

As shown in FIGS. 13A, 13B, first penetrating holes 27 which penetrate the insulating substrate 22 are provided in the insulating substrate 22, and the transparent electrode layer 25 and second back face electrode layer 26 are electrically connected via the first penetrating holes 27. As shown in FIGS. 14A, 14B, second penetrating holes 28 which penetrate the insulating substrate 22 are provided in the insulating substrate 22, and the rear face electrode layer 23a and first back face electrode layer 23b are electrically connected via the second penetrating holes 28.

As shown in FIG. 12, all of the layers stacked on the one face on the light-receiving face side F of the insulating substrate 22 (the rear face electrode layer 23a, photoelectric conversion layer 24, and transparent electrode layer 25) are divided by first patterning lines 29, and all of the layers stacked on the other face on the side opposite the light-receiving face R of the insulating substrate 22 (the first back face electrode layer 23b and second back face electrode layer 26) are divided by second patterning lines 30. By this means, the layers stacked on the insulating substrate 22 are divided into a plurality of unit cells.

Here, the first patterning lines 29 and second patterning lines 30 are disposed alternately in the insulating substrate 22. The isolation positions of the electrode layers on the two faces, on the light-receiving face side F and on the side opposite the light-receiving face R of the insulating substrate 22, are mutually shifted, and moreover by connecting the electrode layers on the two faces of the insulating substrate 22 using the second penetrating holes 28, a structure is obtained in which adjacent unit cells are connected in series.

Patent Reference 1 discloses another example of a thin film photovoltaic cell of the prior art. In the thin film photovoltaic cell of Patent Reference 1, a first electrode layer, a photoelectric conversion layer, and a second electrode layer are stacked on one face of a film substrate comprising an electrically insulating resin, and on the opposite side (rear face) of the film substrate are stacked a third electrode layer and a fourth electrode layer.

Patent Reference 2 discloses still another example of a thin film photovoltaic cell of the prior art. In the thin film photovoltaic cell of Patent Reference 2, connecting holes are plugged by printed electrodes comprising a conductive material (see in particular paragraph [0035] and FIG. 27).

Patent Reference 3 indicates that a translucent conductive film is formed on a glass substrate or other translucent substrate, and that patterning grooves are formed by excimer laser irradiation from the lower side or the upper side of the translucent substrate. It is also indicated that an excimer laser is used with a cylindrical lens to form a linear laser light source, and that linear patterning is performed instantaneously, to improve productivity.

Further, Patent Reference 4 indicates that a translucent electrode film is irradiated with KrF excimer laser light, and grooves are formed (see paragraph [0018]).
Patent Reference 1: Japanese Patent Application Laid-open No. 2001-298203
Patent Reference 2: Japanese Patent Application Laid-open No. H6-342924
Patent Reference 3: Japanese Patent Application Laid-open No. S62-42465
Patent Reference 4: Japanese Patent Application Laid-open No. 2005-101384

The above-described configuration of FIG. 12 to FIG. 14B has the following problems. In the configuration of the prior art, when forming the transparent electrode layer 25 such that the transparent electrode layer 25 and the second back face electrode layer 26 do not contact at the second penetrating holes 28, a mask treatment is performed in the vicinity of the second penetrating holes 28. Hence as shown in FIG. 14B, the transparent electrode layer 25 is not formed in the vicinity of the second penetrating holes 28, and thus in the configuration of the prior art, the effective area of the transparent electrode layer 25 has been limited. The second penetrating holes 28 are disposed at a constant interval, taking into account the electrical resistance of the first back face electrode layer 23b and the second back face electrode layer 26, and so on, so that in the insulating substrate 22, regions in which the transparent electrode layer 25 is not formed are provided at a constant interval. Hence, the effective area of the transparent electrode layer 25 is decreased, and there is the problem that the output of the thin film photovoltaic cell 21 is reduced proportionally thereto.

Mask treatment is performed in the vicinity of the second penetrating holes 28, and thus due to contact between the transparent electrode layer 25 and similar on the insulating substrate 22 with the mask, there has been the possibility of damage to the transparent electrode layer 25 and similar on the insulating substrate 22. When there is a damage to a layer on the insulating substrate 22, leakage currents and similar are increased, and thus there has been the problem of an increase in the defect rate when manufacturing thin film photovoltaic cells 21.

Further, in the case of the technique disclosed in Patent Reference 2, connecting holes are plugged by a conductive material, and thus the insulating properties at the connecting holes are inadequate, and there is the problem that leakage currents are increased.

Further, in a structure of a photoelectric conversion element in which on a substrate having an insulating surface, a rear face electrode film, a photoelectric conversion layer comprising amorphous silicon, microcrystalline silicon or another thin film semiconductor film including an nip junction, and a translucent conductive film are stacked, when laser light is used to perform film isolation groove processing, and in particular if the translucent electrode film is irradiated with an excimer laser to form grooves, the photoelectric conversion layer surface which is the layer underlying the translucent electrode film undergoes microcrystallization (with lowered resistance), as indicated in Patent Reference 4 (see paragraph [0018]). Hence as indicated in Patent Reference 4, etching in a later process becomes necessary.

### DISCLOSURE OF THE INVENTION

This invention is devised in the light of such circumstances, and an object thereof is to provide a thin film photovoltaic cell and a method of manufacture thereof, in which the effective area of the transparent electrode layer is expanded and the output of the thin film photovoltaic cell is increased, and moreover the insulating properties at the second penetrating holes are secured, so that the defect rate during manufacture of the thin film photovoltaic cell can be lowered.

In order to resolve the above mentioned problems of the prior art, this invention provides a thin film photovoltaic cell comprising a rear face electrode layer, a photoelectric conversion layer and a transparent electrode layer stacked in this order on one face of an insulating film, and a back face electrode layer deposited on the other face of the insulating substrate, the insulating substrate being divided into a plurality of unit cells by alternately forming patterning lines in the layers stacked on the two faces of the insulating substrate, the transparent electrode layer and the back face electrode layer being electrically connected via a first penetrating hole which penetrates the insulating substrate, the rear face electrode layer and the back face electrode layer being electrically connected via a second penetrating hole which penetrates the insulating substrate, and adjacent unit cells being connected in series, the thin film photovoltaic cell further comprising a transparent electrode layer removal portion in which the transparent electrode layer at least in a region surrounding the second penetrating hole is removed by an ultraviolet pulsed laser, wherein, in the second penetrating hole, the transparent electrode layer and the back electrode layer are electrically insulated.

Further, the back face electrode layer may comprise a first back face electrode layer and a second back face electrode layer, stacked in this order on the other face of the insulating substrate; in this case, a structure is employed in which the transparent electrode layer and the second back face electrode layer are electrically connected via first penetrating holes which penetrate the insulating substrate, the rear face electrode layer and the first back face electrode layer are electrically connected via second penetrating holes which penetrate the insulating substrate, and by using an ultraviolet pulsed laser to remove the transparent electrode surrounding the second penetrating holes, the transparent electrode layer and the second back face electrode layer are electrically insulated.

In a thin film photovoltaic cell of this invention, the insulating substrate is formed from a film material, and the film material is a heat-resistant film of a polyimide, a polyamideimide, or polyethylene naphthalate.

In a thin film photovoltaic cell of this invention, the photoelectric conversion layer is any one of an amorphous semiconductor, an amorphous semiconductor including microcrystals, a dye-sensitized photovoltaic cell, and an organic photovoltaic cell.

In order to resolve the abovementioned problems of the prior art, a method of manufacture of a photovoltaic cell of the present invention includes a step of forming second penetrating holes in an insulating substrate; a step of forming a rear face electrode layer on one face of the insulating substrate, and forming a first back face electrode layer on the other face of the insulating substrate; a step of forming first penetrating holes in the insulating substrate after forming the rear face electrode layer and the first back face electrode layer; a step of stacking a photoelectric conversion layer on the rear face electrode layer; a step of stacking a transparent electrode layer on the photoelectric conversion layer, and stacking a second back face electrode layer on the face on the opposite side of the insulating substrate; a step of dividing the insulating substrate into a plurality of unit cells by alternately forming patterning lines in the layers stacked on the two faces of the insulating substrate; and a step of removing the transparent electrode layer surrounding the second penetrating holes with an ultraviolet pulsed laser.

In a method of manufacture of a photovoltaic cell of the present invention, it is preferable that, as a Raman shift in Raman spectroscopy measurement when the transparent electrode layer surrounding the second penetrating holes is removed by the ultraviolet pulsed laser, if a peak value from 480 to 490 cm⁻¹ is Ia and a peak value from 510 to 520 cm⁻¹ is Ic, then laser processing is performed by Ic/Ia <2. It is still more preferable that laser processing be performed by Ic/Ia <1.5.

In a thin film photovoltaic cell of the present invention, a rear face electrode layer, a photoelectric conversion layer and a transparent electrode layer are stacked in the order accordingly on one face of an insulating substrate, a back face electrode layer is deposited on the other face of the insulating substrate, and by alternately forming patterning lines in the stacked layers on both faces of the insulating substrate, the insulating substrate is divided into a plurality of unit cells. The transparent electrode layer and a second back face electrode layer are electrically connected via first penetrating holes which penetrate the insulating substrate. The rear face electrode layer and the back face electrode layer are electrically connected via second penetrating holes which penetrate the insulating substrate, and adjacent unit cells are connected in series. Transparent electrode layer removal portions are provided in which at least the transparent electrode layer in regions surrounding the second penetrating holes is removed by an ultraviolet pulsed laser, and in the second penetrating hole, the transparent electrode layer and the back electrode layer are electrically insulated. Hence compared with a case in which the vicinity including the second penetrating hole is masked and regions are created in which the transparent electrode layer is not stacked, as in the prior art, the effective area of the transparent electrode layer can be expanded and the output of the thin film photovoltaic cell can be increased.

Further, there is no longer a need to perform mask treatment in the vicinity of the second penetrating holes, as in the prior art, and thus the production yield at the time of manufacture of thin film photovoltaic cells is improved. In addition, there is no longer a need to perform mask treatment in the vicinity of the second penetrating holes, so that contact of the mask with a layer on the substrate and damage to a layer on the substrate no longer occur. Hence there is no longer an increase in leakage currents in the thin film photovoltaic cell, and the defect rate during manufacture of thin film photovoltaic cells can be lowered.

Further, on the periphery of the second penetrating holes, at least the transparent electrode is isolated, and the transparent electrode layer and back face electrode layer are isolated in the power generation region, so that insulating properties can be secured at the second penetrating holes.

Moreover, the processing to remove the transparent electrode layer at least in regions surrounding the second penetrating holes can be performed without the influence of crystallization of the photoelectric conversion layer in the portion for removal processing, so that further etching and other postprocesses of crystallized portions after processing, such as in the prior art, are unnecessary.

### BRIEF DESCRIPTION OF THE DRAWINGS

FIG. 1 is a plan view of a thin film photovoltaic cell showing a first embodiment of the invention;

FIGS. 2A, 2B show cross-sectional views of FIG. 1 of the invention, in which FIG. 2A is the cross-section at line E-E and FIG. 2B is an enlarged view of H in FIG. 2A;

FIGS. 3A, 3B show cross-sectional views of FIG. 1 of the invention, in which FIG. 3A is the cross-section at line G-G and FIG. 3B is an enlarged view of J in FIG. 3A (first embodiment);

FIG. 4 is an enlarged plan view of the second penetrating holes in an embodiment of the invention;

FIG. 5 is a plan view of the thin film photovoltaic cell in a second embodiment of the invention;

FIG. 6 shows a processing apparatus in an embodiment of the invention;

FIG. 7 shows another processing apparatus in an embodiment of the invention;

FIG. 8 is a flowchart for manufacture of a thin film photovoltaic cell in an embodiment of the invention;

FIG. 9A shows Raman spectroscopy measurement results in a state of irradiation of a photoelectric conversion layer comprising amorphous Si with a KrF excimer laser at a laser power density of 175 mJ/cm²;

FIG. 9B shows Raman spectroscopy measurement results in a state of irradiation of a photoelectric conversion layer comprising amorphous Si with a KrF excimer laser at a laser power density of 200 mJ/cm²;

FIG. 9C shows Raman spectroscopy measurement results in a state of irradiation of a photoelectric conversion layer comprising amorphous Si with a KrF excimer laser at a laser power density of 225 mJ/cm²;

FIG. 9D shows Raman spectroscopy measurement results in a state of irradiation of a photoelectric conversion layer comprising amorphous Si with a KrF excimer laser at a laser power density of 250 mJ/cm²;

FIG. 9E shows Raman spectroscopy measurement results when there is no laser processing in a photoelectric conversion layer comprising amorphous Si;

FIG. 10 shows the relation between power density and Ic/Ia of the KrF laser irradiating a photoelectric conversion layer;

FIG. 11 shows the relation between Ic/Ia and resistance value;

FIG. 12 is a plan view of a thin film photovoltaic cell of the prior art;

FIG. 13A is a cross-sectional view along line A-A in FIG. 12, and FIG. 13B is an enlarged view of C in FIG. 13A; and

FIG. 14A is a cross-sectional view along line B-B in FIG. 12, and FIG. 14B is an enlarged view of D in FIG. 14A.

### BEST MODE FOR CARRYING OUT THE INVENTION

Below, embodiments of the invention are explained using the drawings. In all the drawings, the same constituent elements are assigned with the same symbols, and explanations are omitted as appropriate.

### First Embodiment

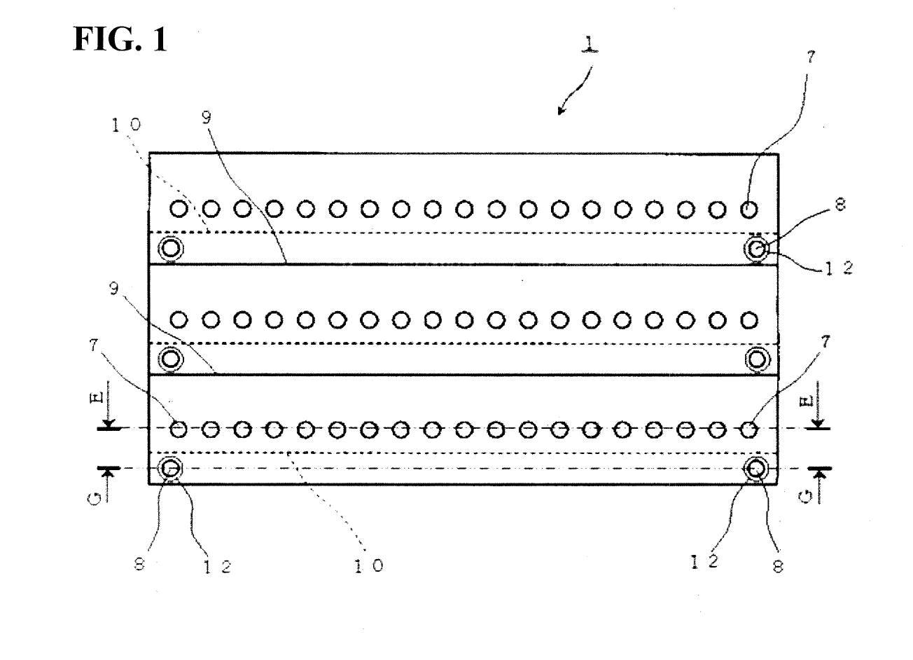

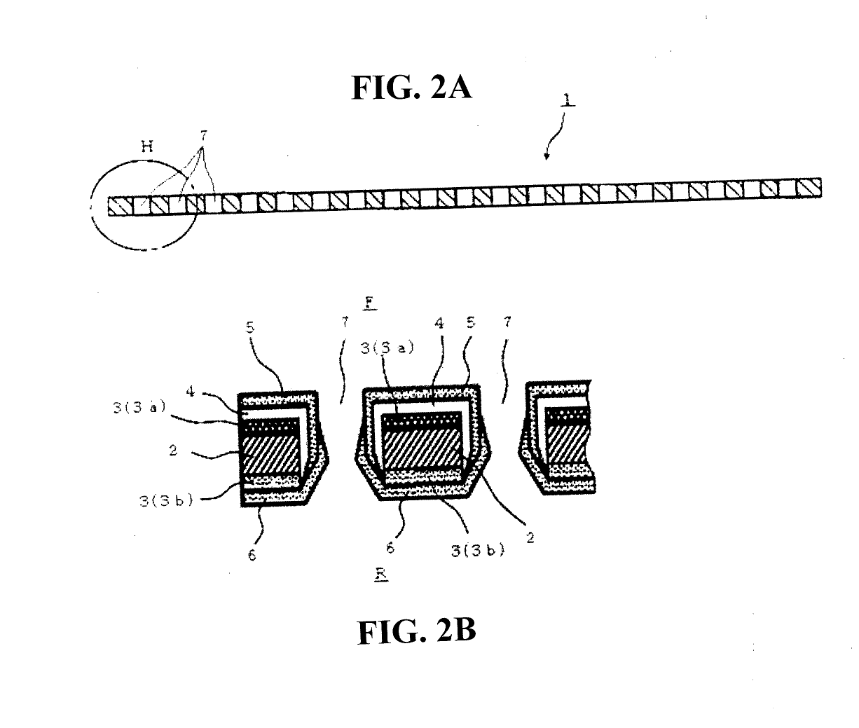

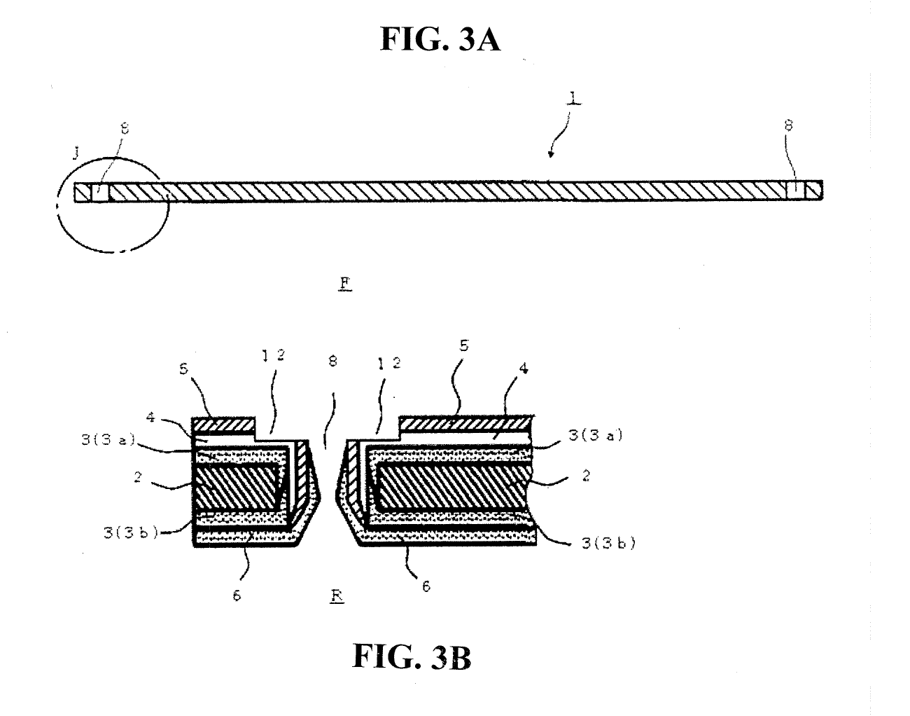

FIG. 1 is a plan view of the thin film photovoltaic cell of a first embodiment. FIG. 2A is a cross-sectional view along line E-E and FIG. 2B is an enlarged view of H in FIG. 2A. FIG. 3A is a cross-sectional view at line G-G in FIG. 1, and FIG. 3B is an enlarged view of J in FIG. 3A.

As shown in FIG. 1, in the thin film photovoltaic cell 1 of the embodiment of the invention, a plurality of first penetrating holes 7 and a plurality of second penetrating holes 8 are provided, and the surface side (light-receiving face side) of the thin film photovoltaic cell 1 is divided by first patterning lines 9 to form a plurality of unit photovoltaic cells. The first patterning lines 9 are configured so as to be delimited by the collection of the first penetrating holes 7 and second penetrating holes 8. The surface side (non-light receiving face side) of the thin film photovoltaic cell 1 is divided by second patterning lines 10 provided at positions which isolate the first penetrating holes 7 and second penetrating holes 8 delimited by the first patterning lines 9.

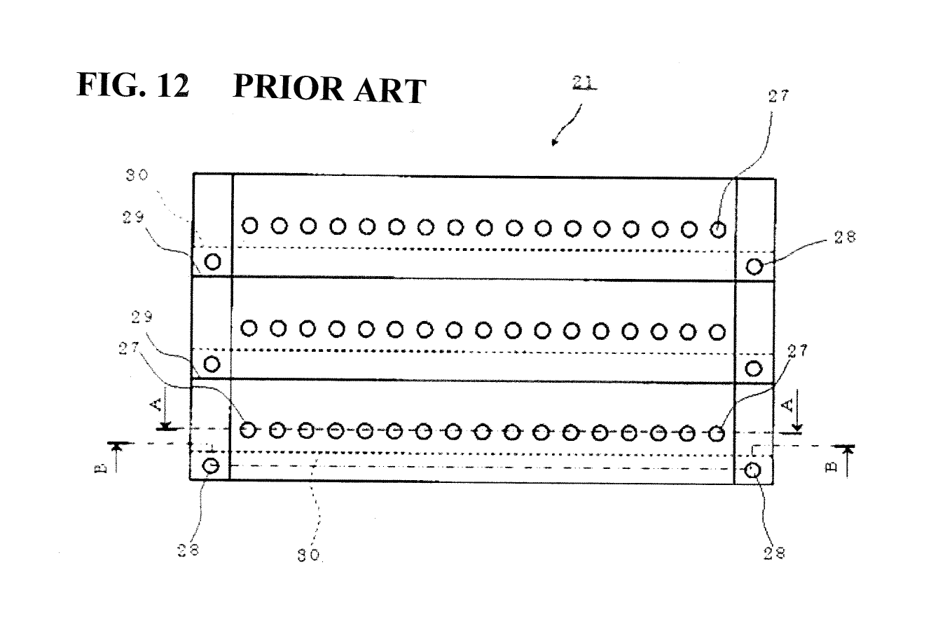

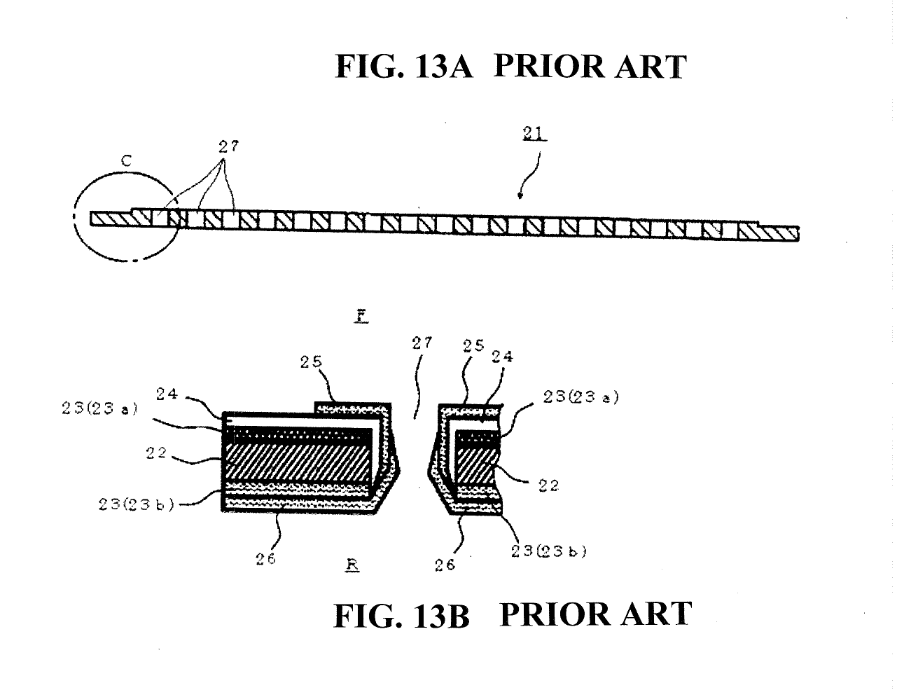

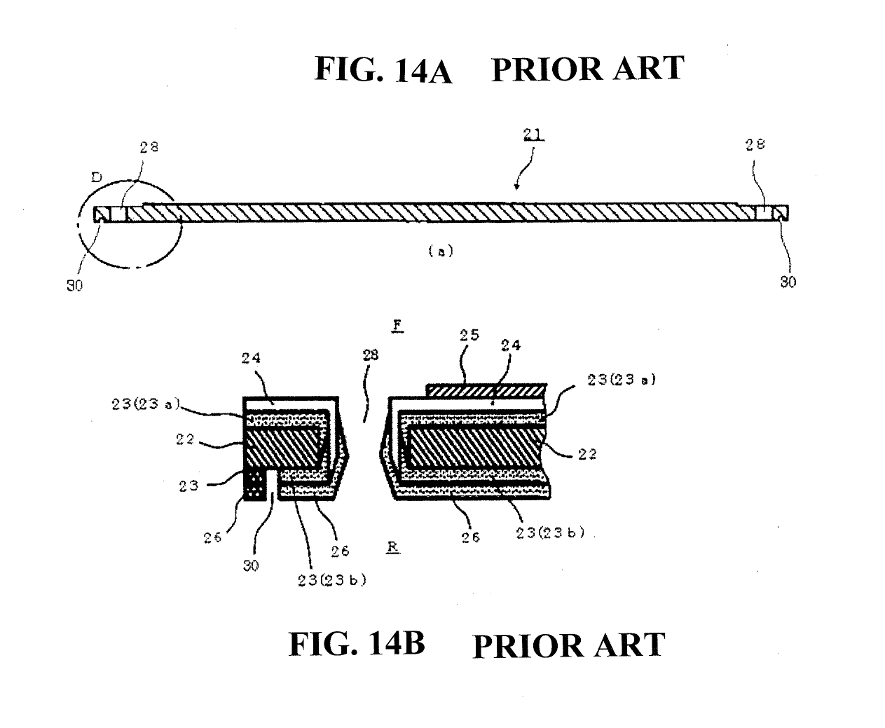

A difference in plan views between the thin film photovoltaic cell 1 of the embodiment of the invention shown in FIG. 1 and the thin film photovoltaic cell 21 of the prior art shown in FIG. 12 is that in FIG. 12, there exist regions on both sides of the thin film photovoltaic cell 21 in which the transparent electrode layer 25 is not deposited, but in FIG. 1, there are no such locations, and the transparent electrode layer (5) exists over the entire faces.

Next, the cross-sectional structure of the thin film photovoltaic cell 1 of the embodiment of the invention is explained, referring to FIGS. 2A, 2B and FIGS. 3A, 3B. The thin film photovoltaic cell 1 of this embodiment comprises an insulating substrate 2. This insulating substrate 2 is formed from a film material, and is for example formed from a polyimide, polyamideimide, or polyethylene naphthalate, or from an aramid or other material.

As shown in FIG. 2B, a metal electrode layer 3 comprising Ag or another metal is formed on both faces of the insulating substrate 2. Here, the metal electrode layer 3 on the face on the light-receiving side, which is the side F, of the insulating substrate 2 functions as a rear face electrode layer 3a, and the metal electrode layer 3 on the face on the side opposite the light-receiving side, which is the side R, of the insulating substrate 2 functions as a first back face electrode layer 3b.

On the rear face electrode layer 3a, a photoelectric conversion layer 4 and a transparent electrode layer 5 are stacked in this order, and on the first back face electrode layer 3b on the other face of the insulating substrate 2, a second back face electrode layer 6 is stacked. On the inner faces (side wall portions) of the first penetrating holes 7 in FIG. 2B, the transparent electrode layer 5 and the second back face electrode layer 6 are electrically connected.

Next, as shown in FIG. 3B, within the second penetrating holes 8, the photoelectric conversion layer 4 and transparent electrode layer 5 are stacked in this order on the rear face electrode layer 3 on the light-receiving face side which is the side F of the insulating substrate 2. On the outer peripheries of the second penetrating holes 8 are provided transparent electrode layer removal portions 12 in which the transparent electrode layer 5 is removed. In the transparent electrode layer removal portions 12, removal includes a portion of the photoelectric conversion layer 4, which contacts the transparent electrode layer 5, or is stacked thereupon with an interface layer, not shown, intervening, and consequently, the conductive transparent electrode layer 5 is completely eliminated.

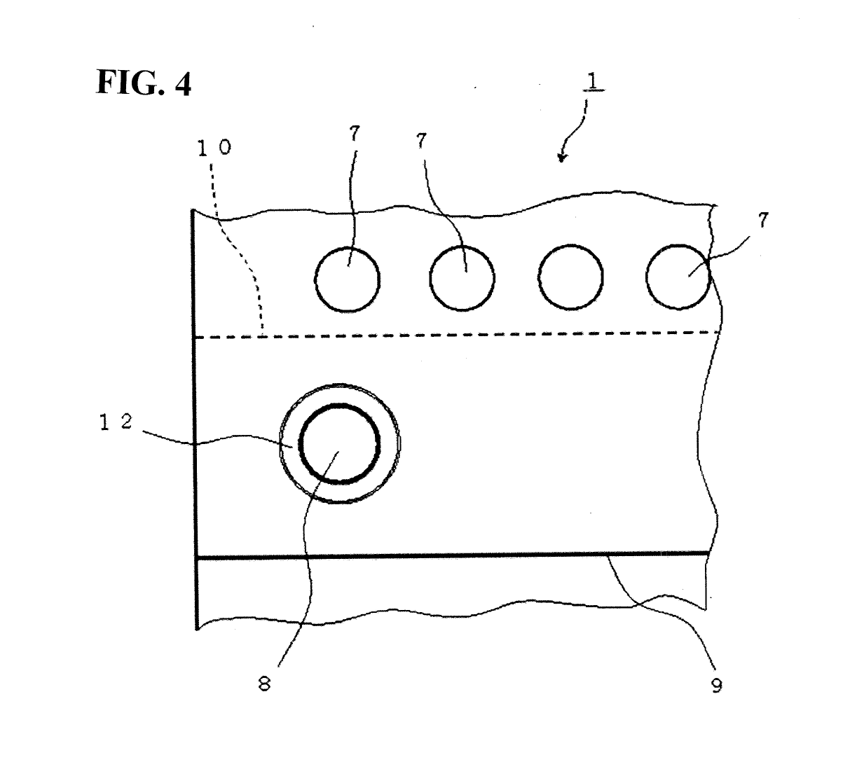

FIG. 4 shows an enlarged plan view of the vicinity of a second penetrating hole 8 in the embodiment of the invention. In FIG. 4, the transparent electrode layer removal portion 12 is formed so as to surround the periphery of the second penetrating hole 8. In the example of FIG. 4, the transparent electrode layer removal portion 12 is formed by removal over a range which is circular and concentric with the second penetrating hole 8, but other configurations are possible, and removal may be over a range which is circular, elliptical, square, rectangular, or polygonal in shape, with center different from that of the second penetrating hole 8, and no limitations in particular are imposed on the shape of formation.

That is, in the configuration of FIG. 3B, the transparent electrode layer 5 on the periphery of the second penetrating hole 8 on the side F of the insulating substrate 2, and the second back face electrode layer 6 which is formed consecutively on the face on the non-light receiving side which is the side R of the insulating substrate 2 from the inner face (side wall portion) of the second penetrating hole 8, are electrically insulated and isolated.

### Second Embodiment

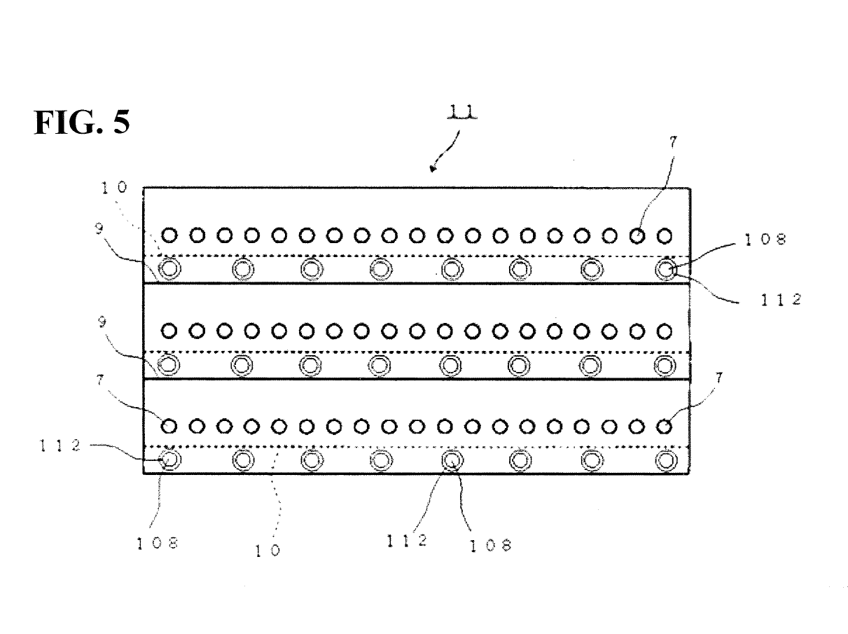

FIG. 5 shows a plan view of the thin film photovoltaic cell of a separate embodiment (second embodiment) of the invention. A difference of the thin film photovoltaic cell 11 of FIG. 5 from the thin film photovoltaic cell of the first embodiment shown in FIG. 1 is the fact that a plurality of second penetrating holes 108 is formed in a row in positions parallel to a row comprising a plurality of first penetrating holes 7. At each second penetrating hole 108 is provided a transparent electrode layer removal portion 112 in which the transparent electrode layer has been removed on the periphery thereof.

As shown in FIG. 3B, the transparent electrode layer removal portion 12 of this invention is formed by using an ultraviolet laser with pulsed oscillation to perform laser removal processing of the transparent electrode layer 5. Here, as the photoelectric conversion layer 4, an amorphous semiconductor, amorphous compound semiconductor, dye-sensitized photovoltaic cell, or organic photovoltaic cell can be used.

The layers (rear face electrode layer 3a, photoelectric conversion layer 4 and transparent electrode layer 5) stacked on the face on the light-receiving side of the insulating substrate 2, which is the side F as shown in FIG. 2B, are divided into a plurality by first patterning lines 9 formed by laser processing using a YAG laser, the second harmonic of a YAG laser, or similar, as shown in FIG. 1.

The layers (first back face electrode layer 3b and second back face electrode layer 6) stacked on the face on the non-light receiving side of the insulating substrate 2, which is the side R, are similarly divided into a plurality by second patterning lines 10 formed by the laser processing shown in FIG. 1. Here, the first patterning lines 9 and second patterning lines 10 are disposed alternately in the insulating substrate 2.

As shown in FIG. 1 and FIGS. 2A, 2B, first penetrating holes 7 which penetrate the insulating substrate 2 are provided in the insulating substrate 2. The transparent electrode layer 5 and second back face electrode layer 6 are connected so as to mutually overlap on the side wall portions of the first penetrating holes 7. By this means, unit cells (unit photovoltaic cells), comprising the layers on the face on the light-receiving side of the insulating substrate 2 which is the side F and the layers on the face on the non-light receiving side which is the side R, are formed.

Further, as shown in FIG. 1 and FIGS. 3A, 3B, second penetrating holes 8 which penetrate the insulating substrate 2 are provided in the insulating substrate 2. The rear face electrode layer 3a and first back face electrode layer 3b are electrically connected via the wide wall portions of the second penetrating holes 8. That is, adjacent unit cells are electrically connected by the second penetrating holes 8. Specifically, the first and second penetrating holes 7 and 8 are used for connection in the order: first and second back face electrode layers 3b and 6→first penetrating holes 7→transparent electrode layer 5→photoelectric conversion layer 4→rear face electrode layer 3a→second penetrating holes 8→first back face electrode layer 3b.

As explained above, by electrically connecting adjacent unit cells in series, a thin film photovoltaic cell 1 is formed. As a characteristic of this embodiment, as shown in FIG. 3B, by forming transparent electrode layer removal portions 12 on the periphery of the second penetrating holes 8, the power generation portion of the transparent electrode layer 5 is electrically insulated and isolated from the back face electrode layer 6, connected through the side wall portions of the second penetrating holes 8.

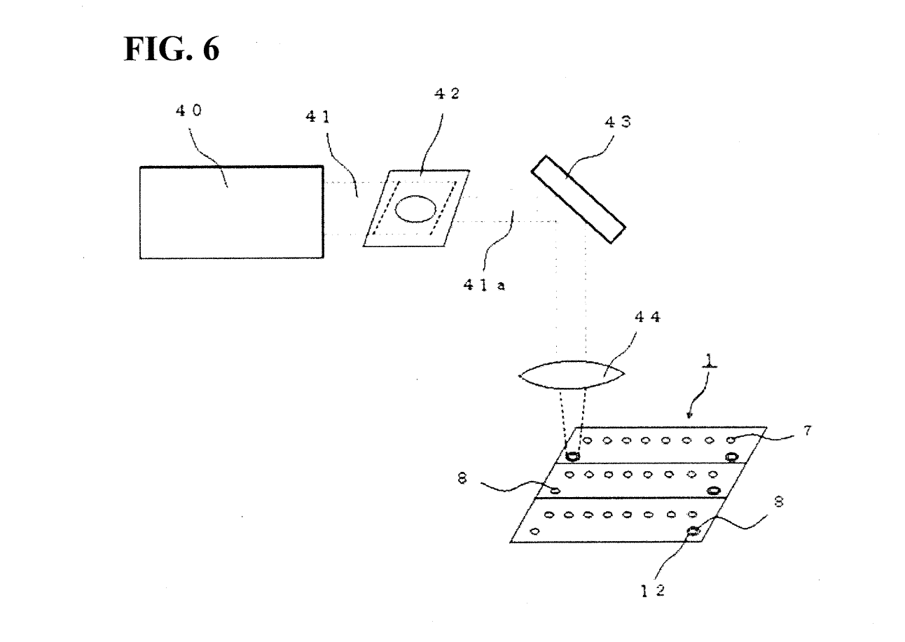

Next, a method of formation of a characteristic portion of the invention is explained using FIG. 6. In a thin film photovoltaic cell 1 of the invention, in order to provide the transparent electrode layer removal portion 12 in which the transparent electrode layer 5 is removed in the outer periphery of the second penetrating holes 8, a pulsed laser is used, and the transparent electrode layer 5 is removed in the transparent electrode layer removal portion 12 by irradiation of a single laser pulse or a plurality of pulses. As the laser, an ArF, KrCl, KrF, XeBr, XeCl, XeF or other excimer laser, an F₂ laser, or another ultraviolet pulsed laser can be used. By performing laser ablation processing using ultraviolet light of oscillation wavelength 380 nm or less, short-circuits due to alteration of the power generation layer (transparent electrode layer 5) in the fabricated portion can be prevented.

In FIG. 6, the ultraviolet laser light 41 from the excimer laser oscillator 40 is made incident on the mask 42 and the laser beam shape is changed, and after being reflected by a reflection mirror 43 and transmitted through a convex lens 44, the laser light irradiates the transparent electrode layer 5 on the periphery of the second penetrating holes 8 of the thin film photovoltaic cell 1 which is the object for processing. In FIG. 6, the mask 42 has holes opened in the same shape as the transparent electrode layer removal portion 12, and the laser light 41a, the shape of which has been changed by the mask 42, is concentrated to a processing size by the convex lens 44, and irradiates the transparent electrode layer removal portion 12.

At this time, the laser optical system may be fixed and a stage on which the processing workpiece, not shown, has been placed may be moved; or, the position of the processing workpiece may be fixed, and a plurality of reflecting mirrors 43 used to move the laser beam position. Further, the convex lens 44 is not always necessary. For example, in a case where numerous second penetrating holes 108 are provided adjacently as in FIG. 5, and similar, a plurality of holes is provided in the mask 42 corresponding to the positions at which a plurality of transparent electrode layer removal portions 112 can be fabricated simultaneously at once over the range of the size of the laser beam from the excimer laser oscillator 40 and the plurality of transparent electrode layer removal portions 112 can be formed simultaneously.

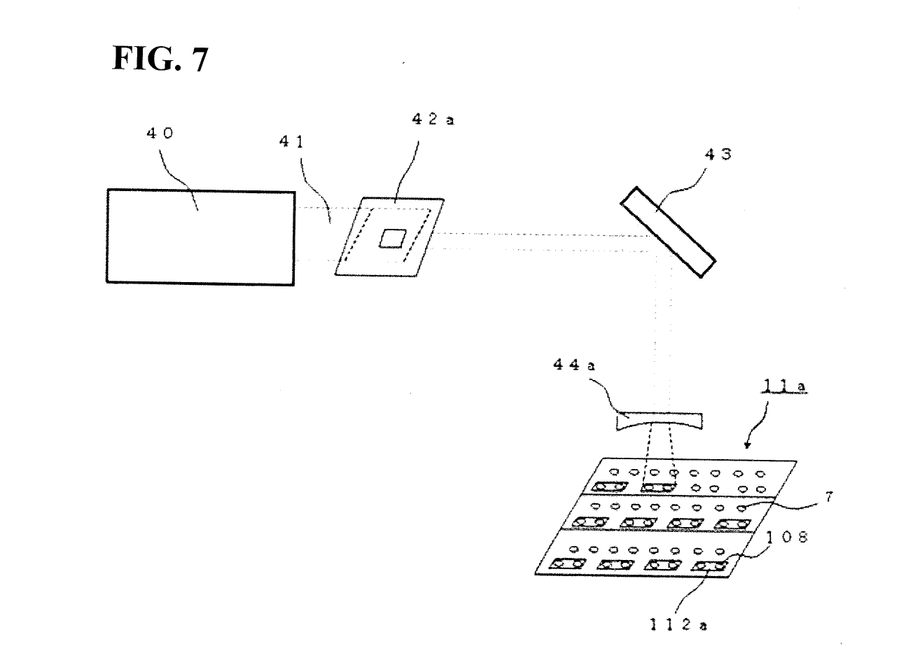

As another method of formation of characteristic portions in this invention, processing can be performed as in FIG. 7. In FIG. 7, when forming the plurality of second penetrating holes 108 so as to form a row as shown in FIG. 5, a mask 42a having rectangular holes can be used, so that transparent electrode layer removal portions 112a, in which the transparent electrode layer 5 is removed on the periphery of two penetrating holes 108, can be formed using a cylindrical concave lens 44a, as shown in FIG. 7.

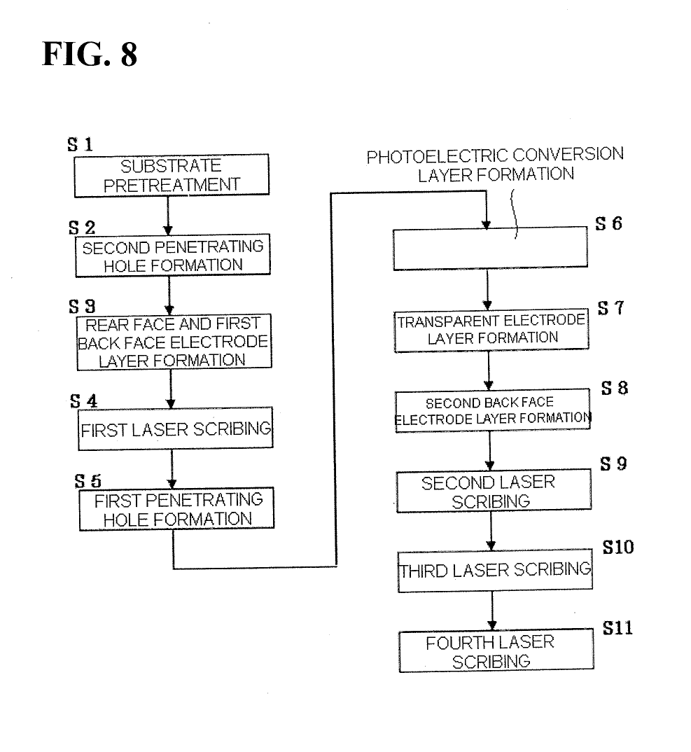

Next, a method of manufacture of a thin film photovoltaic cell of this invention is explained referring to the drawings. FIG. 8 is a flowchart for manufacture of a thin film photovoltaic cell 1 (11, 11a) of this embodiment.

The thin film photovoltaic cell 1 of this embodiment uses a film material such as described above as the insulating substrate 2. As the method of manufacture of the thin film photovoltaic cell 1, a roll-to-roll method and an inkjet printing technique are used. For example, the roll-to-roll method is a method of continuous deposition of thin film on a substrate in a film deposition chamber, within which film material substrate is disposed and transported continuously by a plurality of rolls (transport means).

When manufacturing the thin film photovoltaic cell 1, first in step S1 pretreatment of the insulating substrate 2 is performed, as shown in FIG. 8. Specifically, the surface is cleaned by exposing the insulating substrate 2 to a plasma and other pretreatment is performed.

Next, in step S2, second penetrating holes 8 are formed in the insulating substrate 2. The second penetrating holes 8 are formed by a punching (perforation) method. The shape of the second penetrating holes 8 is circular, with a diameter of 1 mm. The circular diameters of the second penetrating holes 8 can be set in the range 0.05 to 1 mm, and the number of perforations can be adjusted according to the design.

Next, in step S3, a rear face electrode layer 3a and first back face electrode layer 3b are formed on the two faces of the insulating substrate 2 by sputtering treatment. At this time, the rear face electrode layer 3a and first back face electrode layer 3b are electrically connected via the second penetrating holes 8.

Thereafter, in step S4 the layers formed on both faces of the insulating substrate 2 are removed in a linear shape by laser processing to form first patterning lines (not shown). At this time, the lines formed on the two faces of the insulating substrate 2 are mutually shifted.

Then in step S5, first penetrating holes 7 are formed in the insulating substrate 2. The first insulating holes 7 are formed by punching. Next, in step S6, a photoelectric conversion layer 4 is formed on the rear face electrode layer 3a of the insulating substrate 2, and thereafter, in step S7, a transparent electrode layer 5 is formed on the photoelectric conversion layer 4.

Next, in step S8, a second back face electrode layer 6 is formed on the first back face electrode layer 3b of the insulating substrate 2. Next, in step S9, the photoelectric conversion layer 4 and transparent electrode layer 5 on the first patterning lines formed in step S4 are removed again in a linear shape by laser processing, to form first patterning lines 9.

Further, in step S10 the second back face electrode layer 6 on the first patterning lines formed in step S4 are again removed in a linear shape by laser processing to form second patterning lines 10.

In step S11, the transparent electrode layer formed in step S7 is removed by laser processing on the peripheries of the second penetrating holes formed in step S2. By this means, the transparent electrode layer removal portions 12 on the peripheries of the second penetrating holes are isolated from the outside transparent electrode layer 5 and metal electrode layer 3, the layers on the insulating substrate 2 are isolated into a plurality of unit cells by the first and second patterning lines 9 and 10, and series connection of the thin film photovoltaic cell 1 is completed.

In the thin film photovoltaic cell 1 of the embodiment of the invention, the rear face electrode layer 3a, photoelectric conversion layer 4 and transparent electrode layer 5 are stacked in this order on the face on the light-receiving side, which is the side F, of the insulating substrate 2, and the first back face electrode layer 3b and second back face electrode layer 6 are stacked in this order on the face on the non-light receiving side, which is the side R, of the insulating substrate 2. In the thin film photovoltaic cell 1, by alternately forming first and second patterning lines 9 and 10 in the layers stacked on both faces of the insulating substrate 2, the insulating substrate 2 is divided into a plurality of unit cells. The transparent electrode layer 5 and second back face electrode layer 6 are electrically connected via first penetrating holes 7 which penetrate the insulating substrate 2. The rear face electrode layer 3a and first back face electrode layer 3b are electrically connected via second penetrating holes 8 which penetrate the insulating substrate 2. Adjacent unit cells are connected in series. Further, on the peripheries of the second penetrating holes 8, the transparent electrode layer 5 is isolated or removed, so that in the power generation region the transparent electrode and rear face electrode 3 and the back face electrode 6 are isolated.

The method of manufacture of a thin film photovoltaic cell 1 of the first embodiment of the invention includes a step of forming second penetrating holes 8 in the insulating substrate 2; a step of forming the rear face electrode layer 3a on one face 2a of the insulating substrate 2, and forming the first back face electrode layer 3b on the other face 2b of the insulating substrate 2; a step of forming first penetrating holes 7 in the insulating substrate 2 after forming the rear face electrode layer 3a and first back face electrode layer 3b; a step of stacking the photoelectric conversion layer 4 and transparent electrode layer 5 in this order on the side of the one face 2a of the insulating substrate 2, and of stacking the second back face electrode layer 6 on the side of the other face 2b of the insulating substrate 2; a step of alternately forming first and second patterning lines 9 and 10 in the layers stacked on the two faces 2a and 2b of the insulating substrate 2, and dividing the insulating substrate 2 into a plurality of unit cells; and a process of isolating the transparent electrode layer 5 on the peripheries of the penetrating holes 8, so that there is no need to perform mask treatment in the vicinity of the second penetrating holes as in the prior art, and the production yield during manufacture of the thin film photovoltaic cell 1 is improved.

In addition, mask treatment need not be performed in the vicinity of the second penetrating holes 8, so that there is no longer damage to layers on the insulating substrate 2 due to contact of the mask with layers on the insulating substrate 2. Consequently there is no longer an increase in leakage currents in the thin film photovoltaic cell 1, and the defect rate when manufacturing thin film photovoltaic cells 1 can be lowered.

When formation of the transparent electrode layer removal portions 12 isolating the transparent electrode layer 5 is performed for the transparent electrode layer on the periphery of at least one penetrating hole by a single pulse or by a plurality of consecutive pulse shots, treatment time is shortened.

Further, by using an ArF, KrCl, KrF, XeBr, XeCl, XeF or other excimer laser, or an F₂ laser or other ultraviolet pulsed laser as the pulsed laser, the ablation effect of severing and removing molecules is stronger than the influence of heat, and laser processing which prevents short-circuits can be realized.

In this invention, by removing a prescribed depth of the photoelectric conversion layer 4 stacked either in contact with the transparent electrode layer 5 or with an interface layer not shown intervening in transparent electrode layer removal portions during formation of the transparent electrode layer removal portions 12 which isolate the transparent electrode layer 5, the conductive transparent electrode layer 5 is completely eliminated within the transparent electrode layer removal portions 12. Consequently, depending on the laser processing conditions used for the transparent electrode layer removal portions 12, there may be the problems that a phenomenon of reduced resistance may occur due to crystallization at the laser-fabricated photoelectric conversion layer surface, or that the transparent electrode layer 5 on the outer peripheries of the transparent electrode layer removal portions 12 on the periphery of the second penetrating holes 8 and the back electrode layer 6 connected through the side wall portions of the second penetrating holes 8 are not completely electrically insulated and isolated, and leaks may occur.

That is, due to laser irradiation, the effect of heat causes crystallization in the photoelectric conversion layer and reduction of the resistance value. In laser processing using an excimer laser or other ultraviolet laser, the ablation effect is strong and the effect of thermal processing is thought to be low, but when the laser energy is high and a plurality of laser pulse shots is used, crystallization in the photoelectric conversion layer occurs due to the influence of heat.

Here the crystallized portion of the photoelectric conversion layer means at least one portion of the photoelectric conversion layer which has been crystallized (including partial crystallization and microcrystallization) from the amorphous state due to laser irradiation of the photoelectric conversion layer, and is distinguished from a portion of the photoelectric conversion layer which has been partially crystallized as a microcrystal layer due to the conditions at the time of film deposition of the photoelectric conversion layer.

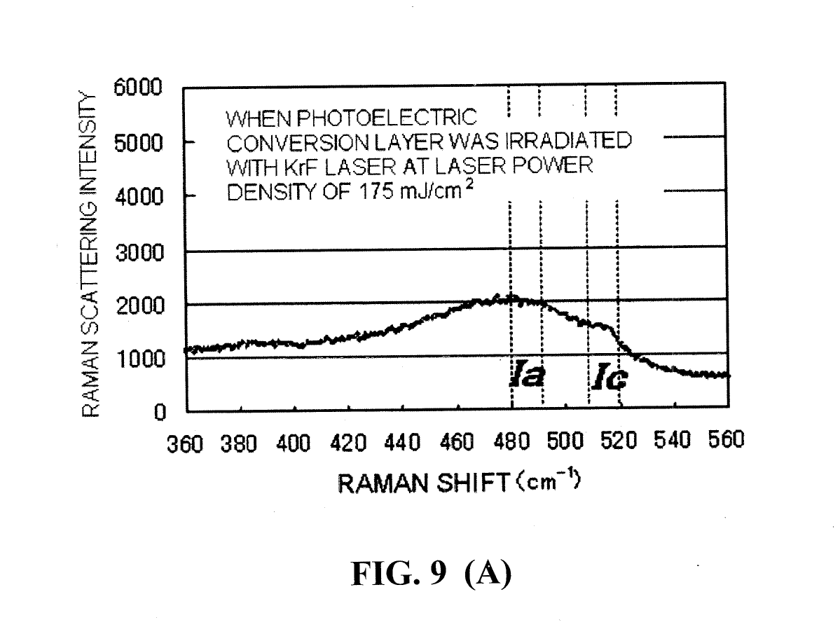

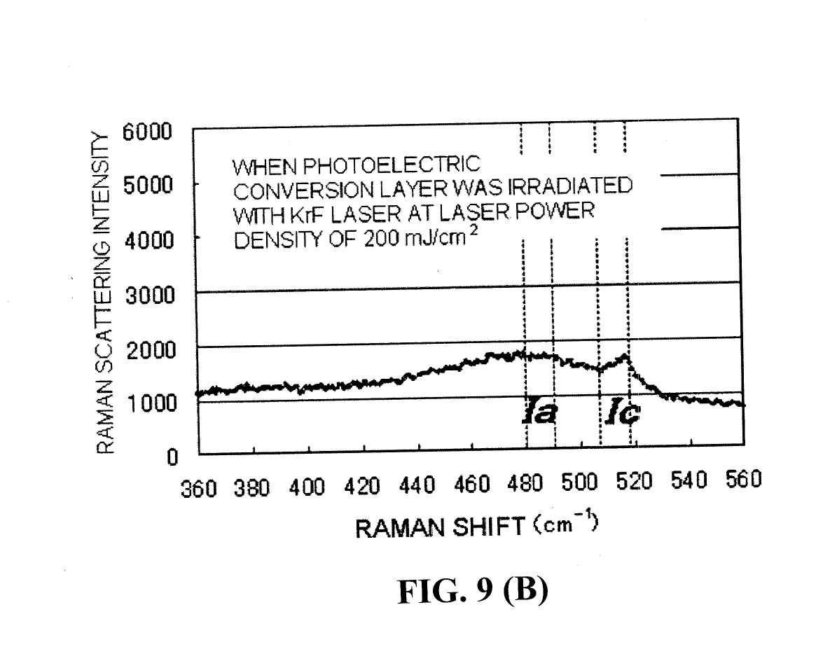

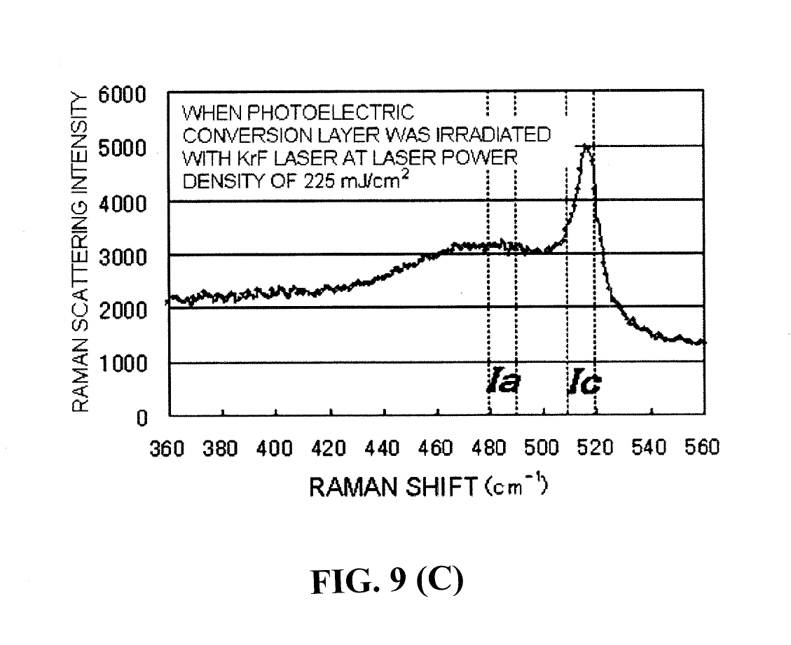

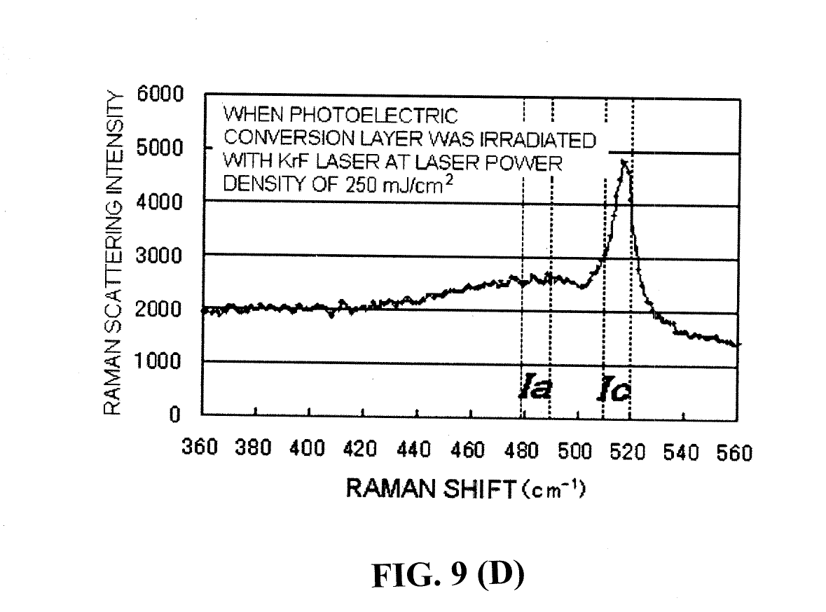

Crystallization in the photoelectric conversion layer can be evaluated by performing Raman spectroscopy measurements. FIGS. 9A-9E show results of Raman spectroscopy measurements in a state in which a photoelectric conversion layer comprising amorphous Si has been irradiated by an excimer laser. FIG. 9A is the Raman spectroscopy measurement results upon irradiation of the photoelectric conversion layer with a KrF laser at a laser power density of 175 mJ/cm². FIG. 9B shows results at 200 mJ/cm². FIG. 9C shows results at 225 mJ/cm². FIG. 9D shows results at 250 mJ/cm². FIG. 9E shows, for comparison, the case in which laser processing was not performed. In FIGS. 9A-9E, the vertical axis indicates the Raman scattering intensity, and the horizontal axis indicates the Raman shift (cm⁻¹).

A Raman shift near 480 to 490 cm⁻¹ indicates an amorphous Si phase state, and a shift near 510 to 520 cm⁻¹ indicates a crystalline Si phase. In FIG. 9A, in which the KrF laser light incident on the photoelectric conversion layer has a power density of 175 mJ/cm², a peak at 510 to 520 cm⁻¹ indicating the existence of a crystalline Si phase cannot be confirmed, and so it can be judged that the phenomenon of resistance reduction due to laser processing does not occur.

Compared with this, in FIG. 9B in which the power density of the KrF laser light incident on the photoelectric conversion layer is 200 mJ/cm², there are cases in which a peak does and does not appear from 510 to 520 cm⁻¹, and it is thought that at this condition an influence on crystallization is beginning to appear. And when the power density of the irradiated KrF laser light raised made still higher, to a power density of 225 mJ/cm² as in FIG. 9C and to 250 mJ/cm² as in FIG. 9D, a peak can be confirmed near 520 cm⁻¹. That is, due to laser processing, the phenomenon of Si crystallization is beginning to appear in the photoelectric conversion layer.

In considering Raman shifts in Raman spectroscopy measurements, if the peak value from 480 to 490 cm⁻¹ indicating the state of an amorphous Si phase is Ia and the peak value from 510 to 520 cm⁻¹ is Ic, then the ratio Ic/Ia is an index which can indicate crystallization.

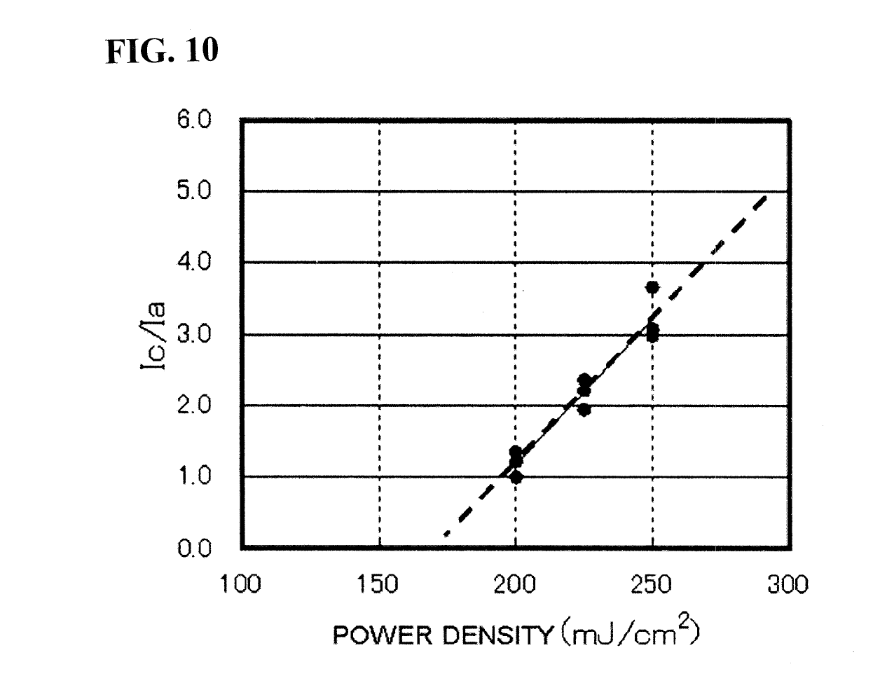

FIG. 10 shows the relation between the power density of a KrF laser irradiating a photoelectric conversion layer and Ic/Ia in FIGS. 9A-9E. From FIG. 10, a linear relationship is obtained between the power density of the laser irradiating the photoelectric conversion layer and Ic/Ia.

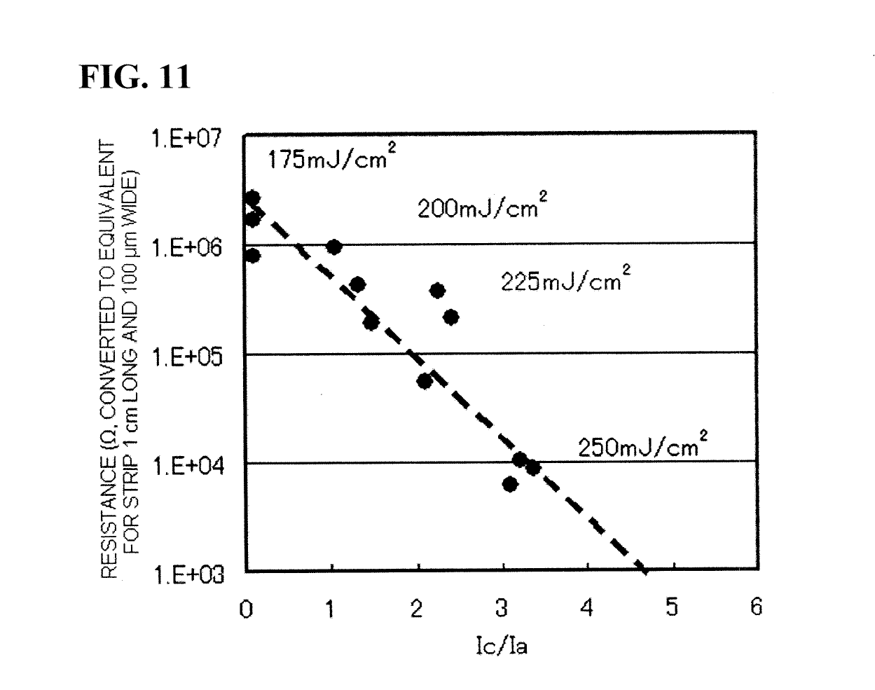

Next, a test piece of length 1 cm with a transparent electrode layer stacked on a photoelectric conversion layer was irradiated with a KrF laser to remove the transparent electrode film over a region of length 1 cm and width 100 μm, and the resistance across the transparent electrode layers on both sides of the 100 μm wide region in which the layer was removed was measured. The results appear in FIG. 11. From FIG. 11 also, it is seen that when the value of Ic/Ia increases, the resistance is reduced, and the insulation becomes inadequate.

From the above results, in the results for the Raman spectroscopy measurements shown in FIGS. 9A-9E, the influence of crystallization in the photoelectric conversion layer surface begin to appear at a KrF laser power density of from 200 mJ/cm² to 225 mJ/cm². That is, the condition is Ic/Ia <2, and preferably the condition Ic/Ia <1.5.

Using actual thin film photovoltaic cells, experiments to remove the transparent electrode layer on the periphery of the second penetrating holes were performed. The results appear in Table 1. A KrF irradiating laser was used.

TABLE 1

| | Energy (J/cm²) | | | | | | | | | |
|---|---|---|---|---|---|---|---|---|---|---|
| | 0.5 | 0.4 | 0.3 | 0.275 | 0.25 | 0.225 | 0.2 | 0.175 | 0.15 | 0.1 |
| 1-pulse | pass | pass | pass | pass | pass | pass | pass | pass | fail | fail |
| transparent | | | | | | | | | | |
| electrode | | | | | | | | | | |
| layer | | | | | | | | | | |
| removal | | | | | | | | | | |
| method | | | | | | | | | | |
| Color of | changed | changed | changed | changed | changed | pass | pass | pass (no | — | — |
| removed | to | to | to | to | to | (no | (no | change) | | |
| portion | black | black | black | black | black | change) | change) | | | |
| Notes | | | | | | | | parts | no | |
| | | | | | | | | remained | change | |
| 2-pulse | | | | | | | | pass | no | no |
| transparent | | | | | | | | | change | change |
| electrode | | | | | | | | | | |
| layer | | | | | | | | | | |
| removal | | | | | | | | | | |
| method | | | | | | | | | | |

At a laser power density of 250 mJ/cm² or higher, changes to a black color in the fabricated locations were confirmed. Hence it is necessary to perform processing under the condition in Table 1 of a power density of 225 mJ/cm² or lower, in agreement with the above-described Raman spectroscopy measurement results.

Further, if the irradiating power density is lowered, up to a power density of 200 mJ/cm², processing is possible using one-pulse irradiation, but if the power density is made 175 mJ/cm², the entire transparent electrode layer cannot be removed with one pulse. However, if irradiation in two pulses is performed, satisfactory processing was possible in which the entire transparent electrode layer was removed.

If the irradiation power density is further lowered to a power density of 150 mJ/cm², a plurality of pulses did not produce an observed change in the transparent electrode layer. As described above, using an ultraviolet pulsed laser, the transparent electrode layer could be removed on the periphery of the second penetrating holes in a thin film photovoltaic cell. Further, results were obtained indicating that as the laser irradiation condition, if the Rama shift peak value obtained in Raman spectroscopy measurements from 480 to 490 cm⁻¹ is Ia and the peak value from 510 to 520 cm⁻¹ is Ic, processing at a laser irradiation intensity such that Ic/Ia <2, is preferable.

### EXPLANATION OF REFERENCE NUMERALS

1, 11, 21 Thin film photovoltaic cell
2, 22 Insulating substrate
3, 23 Metal electrode layer
3a, 23a Rear face electrode layer
3b, 23b First back face electrode layer
4, 24 Photoelectric conversion layer
5, 25 Transparent electrode layer
6, 26 Second back face electrode layer
7, 27 First penetrating hole
8, 28, 108 Second penetrating hole
9, 29 First patterning line
10, 30 Second patterning line
12, 112 Transparent electrode layer removal portion

1. A thin film photovoltaic cell, comprising:
an insulating substrate,
a rear face electrode layer, a photoelectric conversion layer, and a transparent electrode layer stacked in order on one face of the insulating substrate accordingly, and
a back face electrode layer deposited on the other face of the insulating substrate,
wherein the insulting substrate is divided into a plurality of unit cells by alternately forming patterning lines in the layers stacked on two faces of the insulating substrate in which adjacent unit cells are connected in series,
the transparent electrode layer and the back face electrode layer are electrically connected through a first penetrating hole which penetrates the insulating substrate,
the rear face electrode layer and the back face electrode layer are electrically connected through a second penetrating hole which penetrates the insulating substrate,
the thin film photovoltaic cell further comprises a transparent electrode layer removal portion in which the transparent electrode layer is removed in at least a region surrounding the second penetrating hole by an ultraviolet pulsed laser, and
in the second penetrating hole, the transparent electrode layer and the back face electrode layer are electrically insulated.

2. A thin film photovoltaic cell according to claim 1, wherein the insulating substrate is formed from a film material.

3. A thin film photovoltaic cell according to claim 2, wherein the film material is a heat-resistant film formed from a polyimide, a polyamideimide, or polyethylene naphthalate.

4. A thin film photovoltaic cell according to claim 3, wherein the photoelectric conversion layer is any one of an amorphous semiconductor, an amorphous compound semiconductor, a dye-sensitized photovoltaic cell, or an organic photovoltaic cell.

5. A method of manufacture of a thin film photovoltaic cell, comprising the steps of:
forming a second penetrating hole in an insulating substrate;
forming a rear face electrode layer on one face of the insulating substrate, and forming a first back face electrode layer on the other face of the insulating substrate;
forming a first penetrating hole in the insulating substrate after forming the rear face electrode layer and the first back face electrode layer;
stacking a photoelectric conversion layer on the rear face electrode layer;
stacking a transparent electrode layer on the photoelectric conversion layer, and stacking a second back face electrode layer on the other face of the insulating substrate;
dividing the insulating substrate into a plurality of unit cells by alternately forming patterning lines in the layers stacked on two faces of the insulating substrate; and
removing the transparent electrode layer on a periphery of the second penetrating hole with an ultraviolet pulsed laser.

6. A method of manufacture of a thin film photovoltaic cell according to claim 5, wherein, as a Raman shift in Raman spectroscopy measurement when removing the transparent electrode layer on the periphery of the second penetrating hole by the ultraviolet pulsed laser, if a peak value from 480 to 490 cm⁻¹ is Ia and a peak value from 510 to 520 cm⁻¹ is Ic, then laser processing is performed by Ic/Ia <2.

7. The method of manufacture of a thin film photovoltaic cell according to claim 5, wherein, as a Raman shift in Raman spectroscopy measurement when the transparent electrode layer on the periphery of the second penetrating hole is removed by the ultraviolet pulsed laser, if a peak value from 480 to 490 cm⁻¹ is Ia and a peak value from 510 to 520 cm⁻¹ is Ic, then laser processing is performed by Ic/Ia <1.5.
